(19) United States
(12) Patent Application Publication
(10) Pub. No.: US 2026/0020417 A1
(43) Pub. Date: Jan. 15, 2026

(54) LIGHT-EMITTING DIODE PACKAGE

(71) Applicant: Lextar Electronics Corporation, Hsinchu City (TW)

(72) Inventors: Fu-Hsin CHEN, Hsinchu City (TW); Juei-Ho TANG, Hsinchu City (TW); Chun-Min LIN, Hsinchu City (TW); Kai-Hung CHENG, Hsinchu City (TW)

(21) Appl. No.: 19/264,543

(22) Filed: Jul. 9, 2025

(30) Foreign Application Priority Data
Jul. 10, 2024 (TW) 113125744

(51) Int. Cl. H10H 29/856; H01L 25/075; H10H 29/24; H10H 29/85; H10H 29/851; H10H 29/853; H10H 29/854

(52) U.S. Cl. CPC H10H 29/856; H10H 29/24; H10H 29/8508; H10H 29/851; H10H 29/853; H10H 29/854; H01L 25/0753

(57) ABSTRACT

A light-emitting diode (LED) package is provided, which includes a plurality of LED units, an encapsulant, and a first light guide. The encapsulant covers the LED units and has a recessed portion. The recessed portion is between the LED units, and the encapsulant has a plurality of side surfaces surrounding the LED units and the recessed portion. The first light guide is disposed in the recessed portion of the encapsulant, wherein the first light guide has a top portion and a bottom portion, with the top portion having a larger area than the bottom portion. The first light guide includes a plurality of reflective surfaces between the top portion and the bottom portion, and each reflective surface corresponds to a respective LED unit to reflect a portion of the light emitted from the LED units toward the side surfaces of the encapsulant.

### CROSS REFERENCE TO RELATED APPLICATIONS

This application claims priority of Taiwan Patent Application No. 113125744, filed on Jul. 10, 2024, the entirety of which is incorporated by reference herein.

### BACKGROUND

### Field of the Disclosure

The present disclosure relates to a light-emitting diode package, and, in particular, it relates to a light-emitting diode package capable of enhancing the light-emitting angle.

### Description of the Related Art

With the widespread application of electronic products, the demand for improving light-emitting performance of light-emitting diodes (LEDs) in electronic products has been gradually increasing. To address this, LED packaging technology has been undergoing continuous improvements. However, light-emitting devices with multiple LED packages often suffer from uneven brightness. For example, the brightness of a single LED package may be too high, or dark bands may appear between adjacent LED packages, thereby reducing the overall brightness uniformity of the light-emitting device. Therefore, although existing LED packages have gradually met their intended purposes, they do not meet requirements in all respects. There are still problems to be overcome regarding LED packages.

### BRIEF SUMMARY

In some embodiments, a light-emitting diode (LED) package is provided. The LED package includes a plurality of LED units, an encapsulant, and a first light guide. The encapsulant covers the LED units and has a recessed portion. The recessed portion is between the LED units, and the encapsulant has a plurality of side surfaces surrounding the LED units and the recessed portion. The first light guide is disposed in the recessed portion of the encapsulant, wherein the first light guide has a top portion and a bottom portion, with the top portion having a larger area than the bottom portion. The first light guide includes a plurality of reflective surfaces positioned between the top portion and the bottom portion, and each reflective surface corresponds to a respective LED unit to reflect a portion of the light emitted from the LED units toward the side surfaces of the encapsulant.

In some embodiments, an LED package is provided. The LED package includes an LED unit, an encapsulant, and a first light guide. The encapsulant covers the LED unit, wherein the encapsulant has a recessed portion, the recessed portion is positioned corresponding to the LED unit, and the encapsulant has a plurality of side surfaces surrounding the LED unit and the recessed portion. The first light guide is disposed in the recessed portion of the encapsulant, wherein the first light guide has a top portion and a bottom portion, with the top portion having a larger area than the bottom portion. The first light guide includes a reflective surface positioned between the top portion and the bottom portion, and the reflective surface reflects a portion of light emitted from the LED unit toward the side surfaces of the encapsulant.

The LED package of the present disclosure may be applied in a variety of electronic devices. In order to make the features and advantages of the present disclosure more comprehensible, various embodiments are specifically cited herein, together with the accompanying drawings, to be described in detail as follows.

### BRIEF DESCRIPTION OF THE DRAWINGS

Aspects of the present disclosure are best understood from the following detailed description when read with the accompanying figures. It should be noted that in accordance with the standard practice in the industry, various features are not drawn to scale. In fact, the dimensions of the various features may be arbitrarily increased or reduced for clarity of discussion.

FIGS. 1 to 12 are cross-sectional views illustrating LED packages according to some embodiments of the present disclosure.

FIGS. 13 to 16 are top views illustrating LED packages according to some embodiments of the present disclosure

### DETAILED DESCRIPTION OF THE DISCLOSURE

The following disclosure provides many different embodiments or examples for implementing the provided apparatus. Specific examples of various components and their configurations are described below to simplify the embodiments of the present disclosure, but are certainly not intended to limit the present disclosure. For example, if the description mentions that a first component is formed on a second component, it may include an embodiment in which the first component and the second component are in direct contact, and it may also include an embodiment in which an additional component is formed between the first component and the second component so that the first component and the second component are not in direct contact. Furthermore, the present disclosure may repeat element numerals and/or characters in different embodiments or examples. This repetition is for the purpose of brevity and clarity and is not intended to indicate a relationship between the various embodiments and/or examples discussed.

In some embodiments of the present disclosure, terms such as “disposed”, “connected” and the like, unless otherwise defined, may refer to two components being in direct contact, or may refer to two components not being in direct contact, with an additional junction component between the two structures. Terms related to being arranged and connected may also include situations where both structures are movable, or both structures are fixed.

In addition, the terms “first”, “second” and similar terms mentioned in this specification or the scope of the patent application are used to name different components or distinguish different embodiments or scopes, and are not used to limit the upper or lower limit of the number of components, nor are they used to limit the manufacturing order or setting order of the components.

As used herein, the terms “approximate,” “about,” and “substantially” generally mean within 10%, or within 5%, or within 3%, or within 2%, or within 1%, or within 0.5% of a given value or range. The quantities given here are approximate quantities, that is, even if there is no specific description of “about”, “approximately”, or “substantially”, the meanings of “about”, “approximately”, or “substantially” may still be implied. The term “a range between a first value and a second value” means that the range includes the first value, the second value, and other values therebetween. Furthermore, there may be a certain error between any two values or directions used for comparison. If a first value is equal to a second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meanings as commonly understood by one of ordinary skill in the art. It is understood that these terms, such as those defined in commonly used dictionaries, should be interpreted as having meanings consistent with the background or context of the relevant technology and the present disclosure, and should not be interpreted in an idealized or overly formal manner unless specifically defined in the embodiments of the present disclosure.

It should be understood that, for the sake of clarity, some elements of the device are omitted in the drawings, and only some elements are schematically illustrated. In some embodiments, additional components may be added to the devices described below. In other embodiments, some of the components of the apparatus described below may be replaced or omitted. It should be understood that in some embodiments, additional operating steps may be provided before, during and/or after the device manufacturing method. In some embodiments, some of the operation steps described may be replaced or omitted, and the order of some of the operation steps described may be interchangeable.

The present disclosure provides an LED package that enhances the light-emitting angle while reducing the loss of light-emitting efficiency through a specific light-guiding structure.

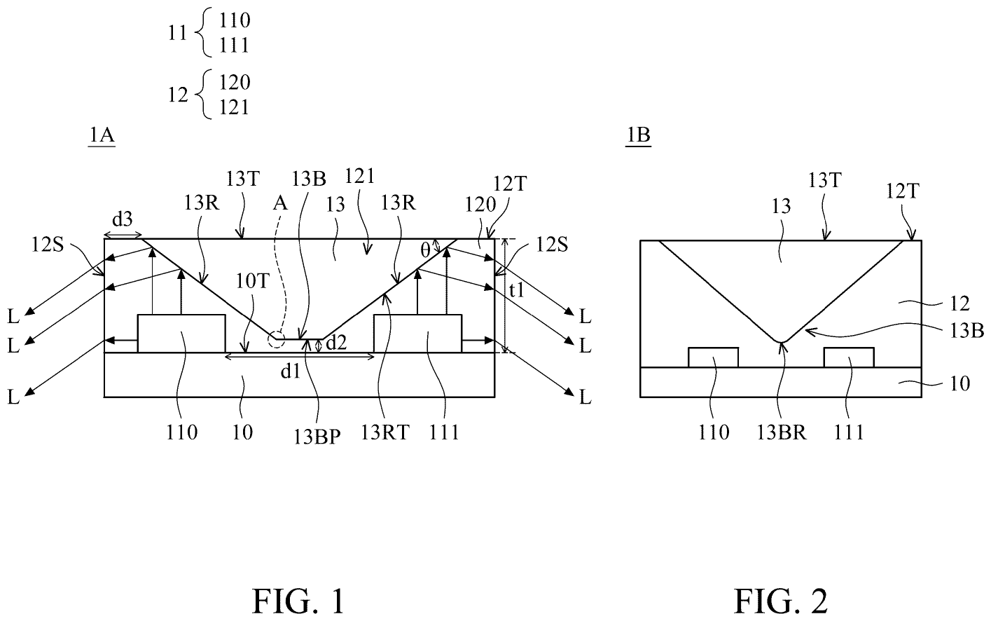

FIG. 1 is a cross-sectional view illustrating the LED package 1A according to some embodiments of the present disclosure. For the sake of simplicity, only a single LED package is shown in the drawings, but the present disclosure is not limited thereto. In some embodiments, the LED package 1A may be applied to different light-emitting devices. For example, a plurality of LED packages 1A may be arranged in series or in parallel on a circuit board. As shown in FIG. 1, the LED package 1A includes a substrate 10, a plurality of LED units 11, an encapsulant 12, and a first light guide 13.

The substrate 10 is used to support components thereon, such as the LED units 11, the encapsulant 12, and the first light guide 13, but the present disclosure is not limited thereto. In some embodiments, the substrate 10 is a substrate with a conductive function, such as a conductive lead frame, a substrate containing a conductive circuit, etc. In some embodiments, the material of the substrate 10 may include glass, quartz, sapphire, ceramic (e.g., alumina (Al₂O₃)), bismaleimide triazine (BT) resin, glass epoxy (e.g., FR-4), epoxy molding compound (EMC), other suitable materials, or a combination thereof, but the present disclosure is not limited thereto. In some embodiments, the substrate 10 may include a light-transmitting substrate, a semi-light-transmitting substrate, or an opaque substrate, but the present disclosure is not limited thereto. In some embodiments, the thickness of the substrate 10 may be between 0.15 mm and 0.85 mm, but the present disclosure is not limited thereto. For example, the thickness of the substrate 10 may be 0.15 mm, 0.2 mm, 0.3 mm, 0.4 mm, 0.5 mm, 0.6 mm, 0.7 mm, 0.85 mm, or any value or range therebetween.

It should be noted that the LED package disclosed herein may be applied not only in the field of Near Chip Scale Package (NCSP) but also in certain applications of Chip Scale Package (CSP). In such cases, the LED package may omit the substrate 10 and adopt the configurations related to the LED units 11, the encapsulant 12, the first light guide 13, or other components mentioned below.

As shown in FIG. 1, the LED units 11 are positioned on the substrate and are used to emit light L. In some embodiments, the LED unit 11 may be a single unit or multiple units. Taking FIG. 1 as an example, the LED units 11 include a first LED unit 110 and a second LED unit 111 that are parallel to each other, and the first LED unit 110 and the second LED unit 111 are respectively positioned on two sides of the first light guide 13. In some embodiments, a distance d1 is provided between the first LED unit 110 and the second LED unit 111, wherein the distance d1 is between 0.15 mm and 0.85 mm, but the present disclosure is not limited thereto. For example, the distance d1 may be 0.15 mm, 0.2 mm, 0.3 mm, 0.4 mm, 0.5 mm, 0.6 mm, 0.7 mm, 0.85 mm, or any value or range therebetween.

In some embodiments, the LED units 11 may include a green LED chip, a red LED chip, or a blue LED chip, but the present disclosure is not limited thereto. For example, a green LED chip may emit green visible light with a wavelength between 510 nm and 570 nm, a red LED chip may emit red visible light with a wavelength between 610 nm and 750 nm, and a blue LED chip may emit blue visible light with a wavelength between 440 nm and 470 nm. In some embodiments, the material of the LED chip may include an inorganic semiconductor material, such as a III-V compound, a II-VI compound, or other suitable materials, but the present disclosure is not limited thereto. It should be noted that the above materials and their combinations are only examples, and the present disclosure may use any materials and their combinations known by a person having skill in the art to form the LED chip in the LED units 11, without being limited thereto.

As shown in FIG. 1, the encapsulant 12 is positioned on the substrate 10 and covers the LED units 11, wherein the encapsulant 12 is used to protect the LED units 11. In some embodiments, the encapsulant 12 includes a light-transmissive portion 120. In some embodiments, the light-transmissive portion 120 includes a light-transmissive material, such as light-transmissive resin, glass, other similar materials, or a combination thereof, but the present disclosure is not limited thereto. In embodiments where the light-transmissive portion 120 includes light-transmissive resin, the light-transmissive portion 120 may include acrylate resin, organic silicone resin, acrylate-modified polyurethane, acrylate-modified organosilicon resin, epoxy, silicone resin, other similar materials, or a combination thereof, but the present disclosure is not limited thereto.

In some embodiments, the encapsulant 12 further includes a wavelength conversion material dispersed within the light-transmissive portion 120. The wavelength conversion material may include materials such as phosphors and quantum dots (QDs) to convert the monochromatic light emitted by each LED chip into light of a specific color. Taking the LED package 1A emitting white light as an example, the first LED unit 110 and the second LED unit 111 may be blue LED chips, and the wavelength conversion material may include yellow phosphor, wherein a portion of the blue visible light emitted by the blue LED chip is absorbed by the yellow phosphor and converted into yellow visible light, and the yellow visible light is mixed with the blue visible light to emit white visible light. Alternatively, the wavelength conversion material may include red phosphor and green phosphor, so that a portion of the blue visible light may be converted into red visible light and green visible light. Therefore, white visible light may be generated by mixing the red visible light, green visible light, and blue visible light inside the LED package 1A. It should be noted that the above wavelength conversion materials and their combinations are only examples, and the present disclosure may use any materials and a combination thereof known by a person having skill in the art to form the wavelength conversion material in the encapsulant 12, without being limited thereto.

In some embodiments, the thickness t1 of the encapsulant 12 may be between 0.3 mm and 0.8 mm, but the present disclosure is not limited thereto. For example, the thickness t1 may be 0.30 mm, 0.35 mm, 0.40 mm, 0.45 mm, 0.50 mm, 0.55 mm, 0.60 mm, 0.65 mm, 0.70 mm, 0.75 mm, 0.80 mm, or any value or range therebetween. When the thickness t1 of the encapsulant 12 is less than 0.30 mm, the encapsulant 12 may not effectively protect the LED units 11 or may not effectively convert visible light of one color into visible light of another color through the wavelength conversion material disposed therein. In addition, when the thickness t1 of the encapsulant 12 is greater than 0.80 mm, the total thickness of the LED package 1A will be oversized.

In some embodiments, the visible light emitted by the LED units 11 are transmitted to the outside via the encapsulant 12. Therefore, the light transmittance (e.g., light transmittance in the visible spectrum) of the encapsulant 12 may be greater than or equal to 80% to provide a better display effect, but the present disclosure is not limited thereto. For example, the light transmittance of the encapsulant 12 may be 80%, 85%, 90%, 95%, 99%, or any value or range therebetween.

As shown in FIG. 1, the encapsulant 12 has a recessed portion 121 for accommodating the first light guide 13. Specifically, the recessed portion 121 is between the LED units 11 (for example, between the first LED unit 110 and the second LED unit 111), and the encapsulant 12 further has a plurality of side surfaces 12S surrounding the LED units 11 and the recessed portion 121.

As shown in FIG. 1, the first light guide 13 is disposed in the recessed portion 121 of the encapsulant 12 and is used to guide the light L emitted by the LED units 11. Specifically, the first light guide 13 has a top portion 13T and a bottom portion 13B, and the area of the top portion 13T is greater than the area of the bottom portion 13B. In some embodiments, the first light guide 13 may include a plurality of reflective surfaces 13R. Each reflective surface 13R is between the top portion 13T and the bottom portion 13B and corresponds to the LED units 11 to reflect a portion of the light L emitted from the LED units 11 toward the side surface 12S of the encapsulant 12. In this way, the field angle of the LED package 1A may be effectively improved and the overall efficiency loss may be reduced.

In some embodiments, each reflective surface 13R of the LED package 1A includes an inclined surface 13RT, and the field angle is related to the inclination of the inclined surface 13RT, wherein the inclination of the inclined surface 13RT may be represented by an angle θ between the reflective surface 13R and the top portion 13T. In some embodiments, the angle θ may be adjusted by controlling the relationship between the area of the top portion 13T and the area of the bottom portion 13B of the first light guide 13. For example, the greater the difference between the area of the top portion 13T and the area of the bottom portion 13B is, the smaller the angle θ is. In some embodiments, the angle θ may be between 20 degrees and 70 degrees, but the present disclosure is not limited thereto. For example, the angle θ may be 20 degrees, 30 degrees, 40 degrees, 50 degrees, 60 degrees, 70 degrees, or any value or range therebetween.

In some embodiments, the contact region A between the bottom portion 13B of the LED package 1A and the reflective surface 13R may have a chamfer (C corner) or a rounded corner (R corner), but the present disclosure is not limited thereto. By chamfering or rounding the contact region A, stress concentration in this area may be avoided.

In some embodiments, the bottom portion 13B of the first light guide 13 has a planar surface 13BP, but the present disclosure is not limited thereto. In some embodiments, a distance d2 is included between the bottom portion 13B of the first light guide 13 and the substrate 10, wherein the distance d2 satisfies: 0.5*LED unit thickness≤d2<LED unit thickness. For example, when the thickness of the LED unit is between 100 μm and 150 μm, the distance d2 may be 50 μm, 55 μm, 60 μm, 65 μm, 70 μm, 75 μm, 100 μm, 120 μm, 130 μm, 140 μm, 150 μm, or any value or range therebetween, but the present disclosure is not limited thereto. When the distance d2 is less than half of the thickness of the LED unit, for example, the distance d2 is less than 50 μm, the bottom portion 13B of the first light guide 13 and the substrate 10 are too close. That is, the gap between them is too small, which may cause the light L on both sides of the first light guide 13 to be difficult to pass through the gap between the first light guide 13 and the substrate 10 for mixing. On the contrary, when the distance d2 is greater than the thickness of the LED unit, for example, greater than 150 μm, the first light guide 13 may be too far away from the substrate 10. As a result, a portion of the light L (for example, the light L moving laterally) may not be reflected by the reflective surface 13R of the first light guide 13.

In some embodiments, the first light guide 13 may not completely cover the top surface of the encapsulant 12. For example, as shown in FIG. 1, the top portion 13T of the first light guide 13 may be coplanar with the top surface 12T of the encapsulant 12, and there is a distance d3 between the top portion 13T of the first light guide 13 and the outermost edge of the top surface 12T of the encapsulant 12, wherein the distance d3 is defined as the first light guide 13 being retracted inward by less than 30% relative to the outermost edge of the encapsulant 12, and the first light guide 13 may be said to be “retracted” relative to the outermost edge of the encapsulant 12.

In some embodiments, the material of the first light guide 13 includes white resin, but the present disclosure is not limited thereto. For example, the first light guide 13 may include a light-transmitting resin and a light-reflecting material dispersed within the light-transmitting resin. In some embodiments, the light-transmitting resin may include acrylate resin, organosilicone resin, acrylate-modified polyurethane, acrylate-modified organosilicone resin, epoxy, silicone resin, other similar materials, or a combination thereof, but the present disclosure is not limited thereto. In some embodiments, the light-reflecting material may include titanium dioxide (TiO₂), other similar materials, or a combination thereof, but the present disclosure is not limited thereto. A higher doping concentration of the light-reflecting material results in a higher light reflectivity of the first light guide 13.

In some embodiments, a portion of the light L emitted by the LED units 11 is reflected by the reflective surface 13R of the first light guide 13, while another portion passes through the first light guide 13 and is transmitted upward. Therefore, in some embodiments, the light transmittance (e.g., light transmittance in the visible spectrum) of the first light guide 13 may be between 20% and 60% to allow a portion of the light L to pass through, but the present disclosure is not limited thereto. For example, the light transmittance of the first light guide 13 may be 20%, 25%, 30%, 35%, 40%, 45%, 50%, 55%, 60%, or any value or range therebetween. In some embodiments, the light reflectivity (e.g., light reflectivity in the visible spectrum) of the first light guide 13 may be between 40% and 80% to effectively reflect the light L, but the present disclosure is not limited thereto. For example, the light reflectivity of the first light guide 13 may be 40%, 45%, 50%, 55%, 60%, 65%, 70%, 75%, 80%, or any value or range therebetween.

In some embodiments, the orthographic projection area of the top portion 13T of the first light guide on the substrate 10 needs to cover more than 40% of the light-emitting area directly above the LED units 11. In more detail, the top portion 13T of the first light guide 13 has an orthographic projection area on the substrate 10, and the orthographic projection area accounts for 40% to 100% of the area of the substrate 10, but the present disclosure is not limited thereto. For example, the orthographic projection area may account for 40%, 45%, 50%, 55%, 60%, 65%, 70%, 75%, 80%, 85%, 90%, 95%, 100% of the area of the substrate 10 or any value or range therebetween. When the orthographic projection area occupies a relatively larger area of the substrate 10, the light L that leaves from directly above the LED package 1A is less, so that the brightness directly above the LED package 1A is relatively small. On the contrary, when the orthographic projection area occupies a relatively smaller area of the substrate 10, relatively more light L leaves from directly above the LED package 1A, so that the brightness directly above the LED package 1A is greater. In other words, the ratio of the orthographic projection area to the area of the substrate 10 may be adjusted according to demand to determine the brightness directly above the LED package.

In some embodiments, the top portion 13T of the first light guide 13 has a rough surface. In some embodiments, the rough surface of the top portion 13T of the first light guide 13 may diffuse (i.e., scatter) the visible light passing through the first light guide 13 to improve the uniformity of the light field.

In the above, some possible aspects of LED packages (e.g., the LED package 1A) have been described, but the present disclosure is not limited thereto. In the following, other possible aspects of the LED packages will be provided. FIGS. 2 to 12 are various cross-sectional views illustrating the LED packages 1B to 1J according to other embodiments of the present disclosure.

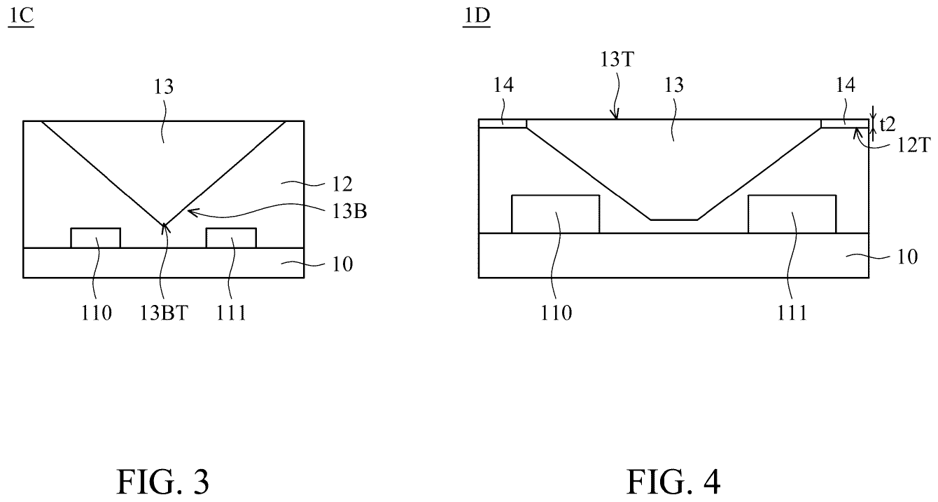

As shown in FIG. 2, in some embodiments, the bottom portion 13B of the first light guide 13 of the LED package 1B may have a chamfer 13BR. For example, the chamfer 13BR may be a rounded corner. As shown in FIG. 3, in some embodiments, the bottom portion 13B of the first light guide 13 of the LED package 1C may also have a pointed tip 13BT. In some embodiments, the distance between the planar surface 13BP (as shown in FIG. 1), the chamfer 13BR (as shown in FIG. 2), or the pointed tip 13BT (as shown in FIG. 3) of the bottom portion 13B and the first LED unit 110 and the distance between the bottom portion 13B and the second LED unit 111 may be equal, but the present disclosure is not limited thereto. In some embodiments, the planar surface 13BP (as shown in FIG. 1), the chamfer 13BR (as shown in FIG. 2), or the pointed tip 13BT (as shown in FIG. 3) of the bottom portion 13B may be closer to either the first LED unit 110 and the second LED unit 111.

As shown in FIG. 4, in some embodiments, the LED package 1D further includes a light diffusion layer 14. The light diffusion layer 14 is disposed on the top surface 12T of the encapsulant 12 and surrounds the top portion 13T of the first light guide 13. In some embodiments, the light diffusion layer 14 may diffuse (i.e., scatter) the light L passing through the light diffusion layer 14 to improve brightness uniformity. In some embodiments, the light transmittance of the light diffusion layer 14 (e.g., light transmittance in the visible spectrum) may be greater than 10%, but the present disclosure is not limited thereto. For example, the light transmittance of the light diffusion layer 14 may be 10%, 20%, 30%, 40%, 50%, 60%, 70%, 80%, 90%, 99%, or any value or range therebetween. In some embodiments, the material of the light diffusion layer 14 includes light-transmitting resin and may not include light-reflective material or other colored particles. In some embodiments, the light transmittance of the light diffusion layer 14 is greater than the light transmittance of the first light guide 13, but the present disclosure is not limited thereto.

In some embodiments, the thickness t2 of the light diffusion layer 14 may be between 20 μm and 200 μm, but the present disclosure is not limited thereto. For example, the thickness t2 of the light diffusion layer 14 may be 20 μm, 30 μm, 40 μm, 50 μm, 60 μm, 75 μm, 100 μm, 125 μm, 150 μm, 175 μm, 200 μm, or any value or range therebetween.

In some embodiments, the top portion 13T of the first light guide 13 and the light diffusion layer 14 have an orthographic projection area on the substrate 10 (i.e., both are projected onto the substrate 10), and the orthographic projection area occupies 40% to 100% of the area of the substrate 10, but the present disclosure is not limited thereto. For example, the orthographic projection area may account for 40%, 45%, 50%, 55%, 60%, 65%, 70%, 75%, 80%, 85%, 90%, 95%, 100%, or any value or range therebetween of the area of the substrate 10.

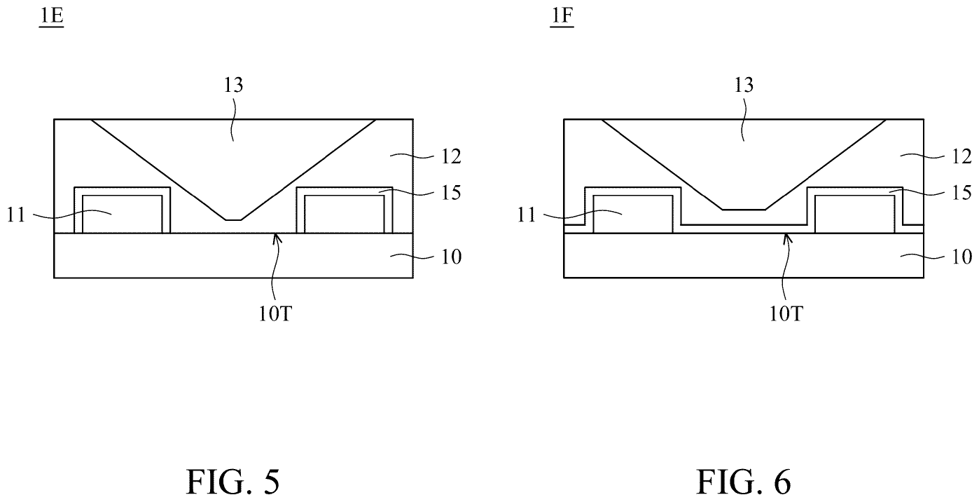

As shown in FIG. 5, in some embodiments, the outer surface of the LED units 11 of the LED package 1E are covered by a wavelength conversion layer 15. For example, the wavelength conversion layer 15 may include a wavelength conversion material, and the wavelength conversion material may include phosphor, quantum dot (QD) material, etc., to convert the monochromatic light emitted by each LED chip into light of a specific color. In these embodiments, the wavelength conversion layer 15 may cover the outer surfaces of the LED units 11 and expose the top surface 10T of the substrate 10. In some embodiments, the wavelength conversion layer 15 on the outer surfaces of each LED units 11 may be different from or the same as each other to convert the same visible light into different visible light, or convert different visible light into the same visible light, but the present disclosure is not limited thereto. As shown in FIG. 6, in other embodiments, the wavelength conversion layer 15 of the LED package IF may be conformally coated on the LED units 11 and the top surface 10T of the substrate 10 to achieve the above-mentioned effects.

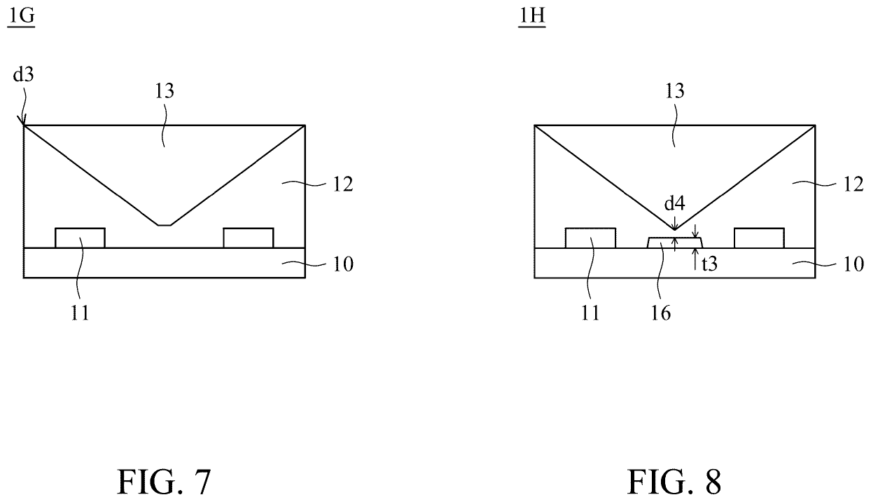

As shown in FIG. 7, in some embodiments, the first light guide 13 of the LED package 1G may completely cover the encapsulant 12. For example, the distance d3 between the outermost edge of the top surface 12T of the encapsulant 12 and the top portion 13T of the first light guide 13 may be substantially 0. In this case, it may be said that the first light guide 13 has “no retraction” relative to the outermost edge of the encapsulant 12.

As shown in FIG. 8, in some embodiments, the LED package 1H may further include a second light guide 16, wherein the second light guide 16 is positioned on the substrate 10 and below the bottom portion 13B of the first light guide 13. In some embodiments, the second light guide 16 may reflect the visible light reflected by the reflective surface 13R or the inner surface of the encapsulant 12, so that the visible light exits from both sides or the top portion of the LED package 1H. In some embodiments, in the cross-sectional view, the second light guide 16 may include a shape such as rectangle, a trapezoid, an ellipse, other suitable shapes, or a combination thereof, but the present disclosure is not limited thereto.

In some embodiments, the light reflectivity (e.g., light reflectivity in the visible spectrum) of the second light guide 16 may be greater than 40%, or may be between 40% and 80%, but the present disclosure is not limited thereto. For example, the light reflectivity of the second light guide 16 may be 40%, 45%, 50%, 55%, 60%, 65%, 70%, 75%, 80%, 85%, 90%, 95%, 99%, or any value or range therebetween.

In some embodiments, the thickness t3 of the second light guide 16 is smaller than the distance d2 between the bottom portion 13B of the first light guide 13 and the substrate 10, and there is a distance d4 between the second light guide 16 and the bottom portion 13B of the first light guide 13. The second light guide 16 may be 40% to 60% of the thickness of the LED units 11, but the present disclosure is not limited thereto. For example, the thickness t3 of the second light guide 16 may be 40%, 42.5%, 47.5%, 50%, 52.5%, 55%, 57.5%, 60%, or any value or range therebetween of the thickness of the LED units 11.

In some embodiments, the material of the second light guide 16 includes white resin, but the present disclosure is not limited thereto. For example, the second light guide 16 may include a light-transmitting resin and a light-reflecting material dispersed within the light-transmitting resin. In some embodiments, the material of the second light guide 16 may be similar to or the same as the material of the first light guide 13, but the present disclosure is not limited thereto.

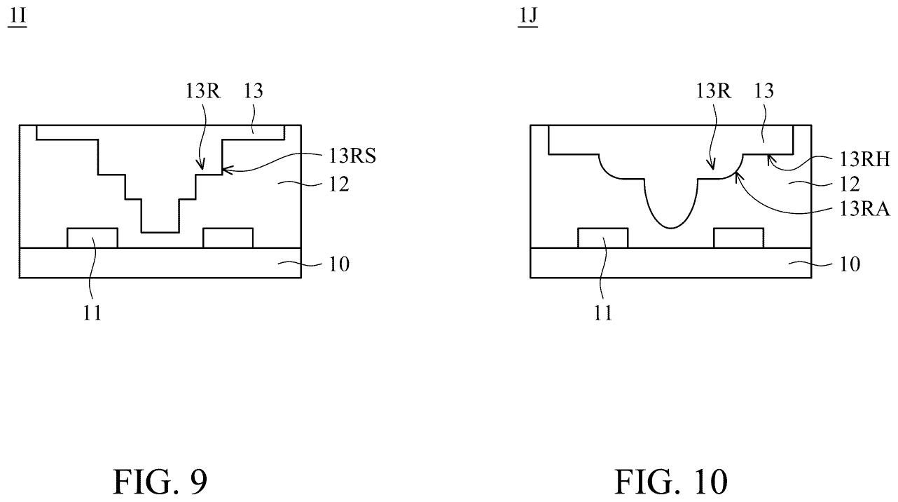

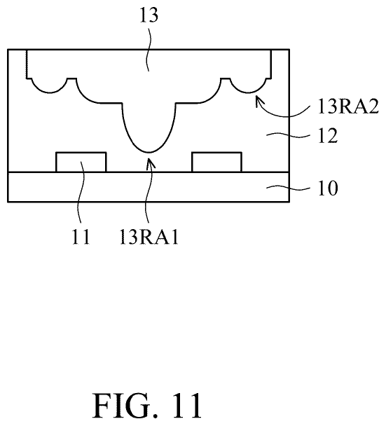

As shown in FIG. 9, in some embodiments, each reflective surface 13R of the LED package 1I includes a stepped structure 13RS. For example, the stepped structure 13RS may be composed of a plurality of vertical surfaces and/or horizontal surfaces, but the present disclosure is not limited thereto. In other embodiments, the stepped structure 13RS may also include the inclined surface as described above. As shown in FIG. 10, in some embodiments, each reflective surface 13R of the LED package 1J includes a horizontal surface 13RH and a plurality of curved surfaces 13RA. As shown in FIG. 11, in some embodiments, each reflective surface 13R of the LED package includes a plurality of curved surfaces 13RA, such as a first curved surface 13RA1 and a second curved surface 13RA2, and the first curved surface 13RA1 and the second curved surface 13RA2 may have the same or different curvatures.

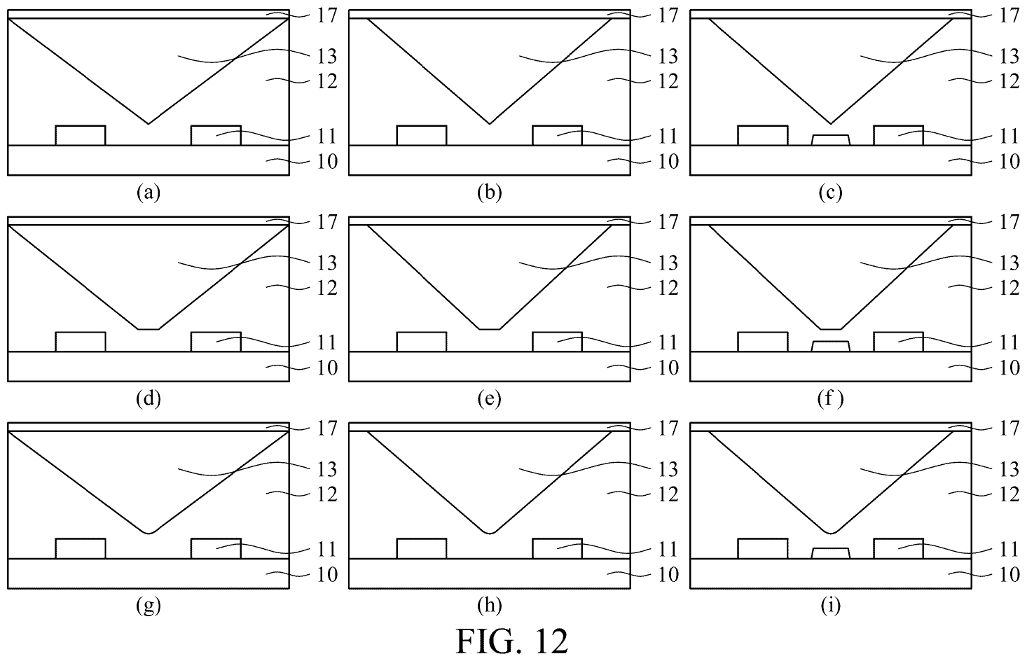

As shown in aspect (a) of FIG. 12, in some embodiments, the LED package 1K further includes a third light guide 17, wherein the third light guide 17 is disposed on the first light guide 13 and is used to guide the light L emitted by the LED units 11. For example, the third light guide 17 may reflect a portion of the light L emitted from the LED units 11 to the side surface 12S of the encapsulant 12. In this way, the field angle of the LED package 1K may be effectively improved.

In some embodiments, the light reflectivity (e.g., light reflectivity in the visible spectrum) of the third light guide 17 may be greater than 40%, or may be between 40% and 80%, but the present disclosure is not limited thereto. For example, the light reflectivity of the third light guide 17 may be 40%, 45%, 50%, 55%, 60%, 65%, 70%, 75%, 80%, or any value or range therebetween.

In some embodiments, the material of the third light guide 17 includes white resin, but the present disclosure is not limited thereto. For example, the third light guide 17 may include a light-transmitting resin and a light-reflecting material dispersed within the light-transmitting resin. In some embodiments, the material of the third light guide 17 may be similar to or the same as the material of the first light guide 13, but the present disclosure is not limited thereto. The thickness t2 of the third light guide 17 may be between 20 μm and 200 μm, but the present disclosure is not limited thereto. For example, the thickness t2 of the third light guide 17 may be 20 μm, 30 μm, 40 μm, 50 μm, 60 μm, 75 μm, 100 μm, 125 μm, 150 μm, 175 μm, 200 μm, or any value or range therebetween.

Referring to aspects (b) to (i) of FIG. 12, in various embodiments, in the cross-sectional views, the shape of the first light guide 13 of the LED package 1K may include: an inverted triangle as shown in aspects (a) to (c); an inverted trapezoid as shown in aspects (d) to (f); or an inverted triangle with chamfer as shown in aspects (g) to (i). Alternatively, in various embodiments, in the cross-sectional views, the shape of the top portion 13T of the first light guide 13 of the LED package 1K may include: extending to both sides of the top portion edge of the encapsulant 12 as shown in the aspects (a), (d), and (g); or extending to the outermost edges on both sides of the encapsulant 12 and retracting inward by a distance as shown in the aspects (b), (e) and (h). Alternatively, in the cross-sectional views, the LED package 1K may further include a second light guide 16 as shown in aspects (c), (f), and (i). By changing the shape of the first light guide 13, the field angle may be adjusted to enhance the applicability of the LED package.

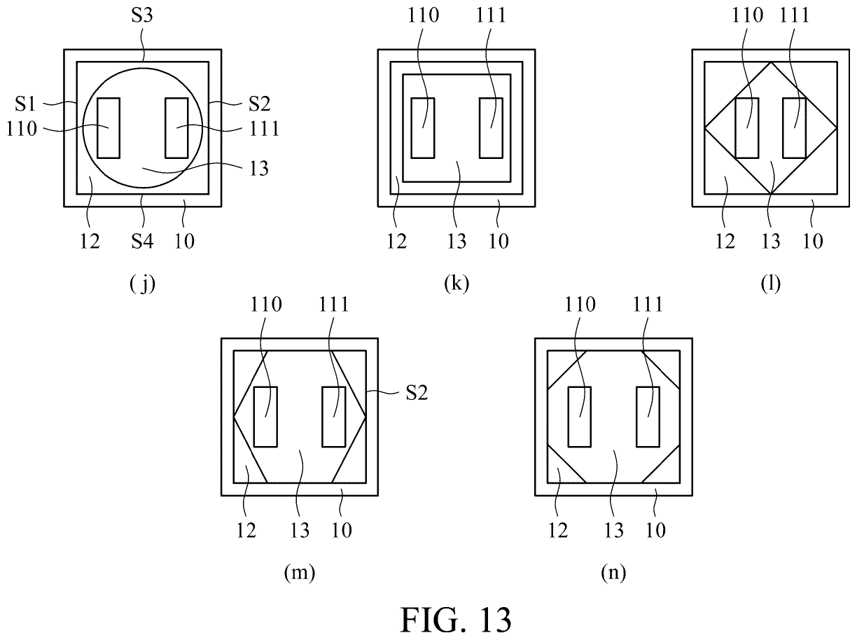

Hereinbefore, the cross-section views of the LED packages have been described according to some embodiments of the present disclosure. The top view shapes of LED packages are described herein according to other embodiments of the present disclosure. FIGS. 13 to 16 are top views of the LED packages according to some embodiments of the present disclosure. In these embodiments, the outer contour of the LED package is substantially shaped as a parallelepiped, such as a cuboid or a cube, and the side surfaces of the encapsulant 12 include a first side surface S1 and a second side surface S2 that are parallel to each other, as well as a third side surface S3 and a fourth side surface S4 that are parallel to each other. The third side surface S3 and the fourth side surface S4 connect the first side surface S1 and the second side surface S2. In addition, as shown in FIGS. 1 to 12, the four side surfaces 12S of the encapsulant 12 are substantially aligned with the four side surfaces of the substrate 10.

As shown in aspects (j) to (n) of FIG. 13, the LED units 11 include a first LED unit 110 and a second LED unit 111 that are respectively positioned on opposite sides of the first light guide 13 and are parallel to each other, wherein the long axes of the first LED unit 110 and the second LED unit 111 are parallel to the first side surface S1 and the second side surface S2 of the encapsulant 12. In some embodiments, in a top view, the top surface of the first light guide 13 may shaped as circular (as shown in aspect (j)), rectangular (as shown in aspect (k)), diamond (as shown in aspect (1)), hexagonal (as shown in aspect (m)), or octagonal (as shown in aspect (n)), but the present disclosure is not limited thereto. In other embodiments, in a top view, the top surface of the first light guide 13 may also shaped as a triangle, an ellipse, a pentagon, other polygons, or a combination thereof, but the present disclosure is not limited thereto. By changing the top surface shape of the first light guide 13, the field angle may be adjusted to enhance the applicability of the LED package.

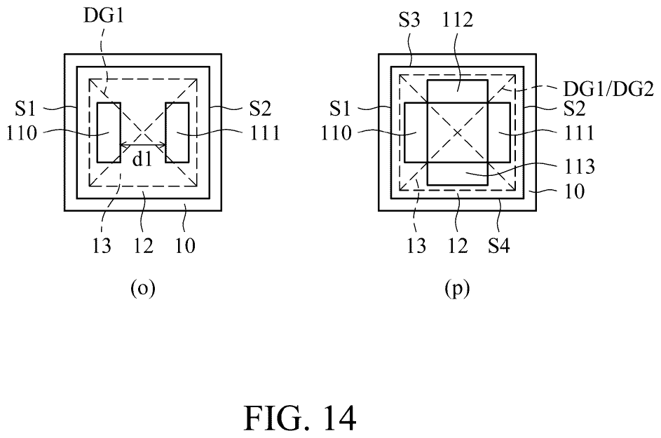

In some embodiments, the LED units 11 are symmetrically arranged around the first light guide 13 with the first light guide 13 serving as a reference. For example, as shown in aspect (o) of FIG. 14, the LED units 11 include a first LED unit 110 and a second LED unit 111 that are respectively positioned on opposite sides of the first light guide 13 and are parallel to each other, wherein the long axes (or long sides) of the first LED unit 110 and the second LED unit 111 are parallel to the first side surface S1 and the second side surface S2 of the encapsulant 12. The first LED unit 110 and the second LED unit 111 are symmetrical to each other with the bottom portion 13B of the first light guide 13 as the center.

In some embodiments where the first LED unit 110 and the second LED unit 111 are symmetrical to each other, a distance d1 is included between the first LED unit 110 and the second LED unit 111, wherein the distance d1 may be between 0.2 mm and 0.85 mm, but the present disclosure is not limited thereto. For example, the distance d1 may be 0.2 mm, 0.3 mm, 0.4 mm, 0.5 mm, 0.6 mm, 0.7 mm, 0.85 mm, or any value or range therebetween.

Alternatively, as shown in aspect (p) of FIG. 14, the LED units 11 further include a third LED unit 112 and a fourth LED unit 113 that are positioned on two opposite sides of the first light guide 13 and are parallel to each other, wherein the long axes of the third LED unit 112 and the fourth LED unit 113 are parallel to the third side surface S3 and the fourth side surface S4 of the encapsulant 12. The four LED units 11 are symmetrically arranged in pairs around the bottom portion 13B of the first light guide 13 as the center, and the third LED unit 112 and the fourth LED unit 113 are adjacent to the first LED unit 110 and the second LED unit 111 to form a quadrilateral. In the top view of the LED package, the substrate 10 has a first diagonal line DG1, and the quadrilateral formed by the first LED unit 110 to the fourth LED unit 113 has a second diagonal line DG2. The first diagonal line DG1 overlaps the second diagonal line DG2.

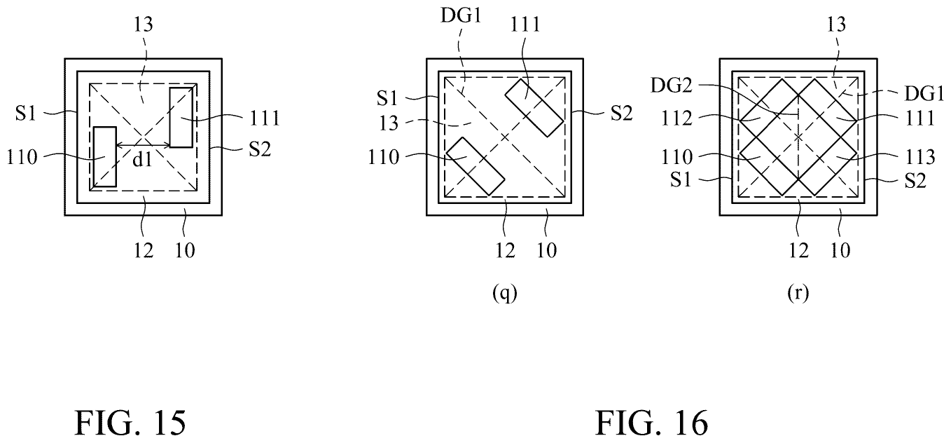

In some embodiments, the LED units 11 are asymmetrically arranged around the first light guide 13 with the first light guide 13 serving as a reference. For example, as shown in FIG. 15, the LED units 11 include a first LED unit 110 and a second LED unit 111 that are respectively positioned on opposite sides of the first light guide 13 and are parallel to each other, wherein the long axes of the first LED unit 110 and the second LED unit 111 are parallel to the first side surface S1 and the second side surface S2 of the encapsulant 12. Different from the embodiment of FIG. 14, the two LED units 11 (e.g., the first LED unit 110 and the second LED unit 111) of FIG. 15 are asymmetric to each other with the bottom portion 13B of the first light guide 13 as the center. By making the LED units 11 asymmetric to each other, the field angle may be adjusted to improve the applicability of the LED package.

In some embodiments where the first LED unit 110 and the second LED unit 111 are asymmetric to each other, a distance d1 is included between the first LED unit 110 and the second LED unit 111, wherein the distance d1 may be between 0.15 mm and 0.70 mm, but the present disclosure is not limited thereto. For example, the distance d1 may be 0.15 mm, 0.2 mm, 0.3 mm, 0.4 mm, 0.5 mm, 0.6 mm, 0.7 mm, or any value or range therebetween.

In some embodiments, the LED units 11 may also rotate relative to the substrate 10 (or the encapsulant 12 or the first light guide 13 thereon). For example, as shown in aspect (q) of FIG. 16, the LED units 11 include a first LED unit 110 and a second LED unit 111 that are positioned on opposite sides of the first light guide 13 and are parallel to each other, wherein the long axes of the first LED unit 110 and the second LED unit 111 are not parallel to the first side surface S1 and the second side surface S2 of the encapsulant 12. In some embodiments, there is an angular difference between the long axis of the LED units 11 and the first side surface S1 or the second side surface S2. For example, the angular difference may be 45 degrees, but the present disclosure is not limited thereto. By rotating the LED units 11 relative to the substrate 10, the field angle may be adjusted to improve the applicability of the LED package.

Alternatively, as shown in the aspect (r) of FIG. 16, the LED units 11 further include a third LED unit 112 and a fourth LED unit 113 that are positioned on two opposite sides of the first light guide 13 and are parallel to each other. In the top view of the LED package, the substrate 10 has a first diagonal line DG1, and the quadrilateral formed by the first LED unit 110 to the fourth LED unit 113 has a second diagonal line DG2, and the first diagonal line DG1 and the second diagonal line DG2 have an angular difference. For example, the angular difference between the first diagonal line DG1 and the second diagonal line DG2 may be 45 degrees, but the present disclosure is not limited thereto. As described above, the present disclosure provides an LED package, which effectively improves the field angle by disposing a first light guide. Furthermore, the present disclosure also adjusts the field angle more accurately by changing the size, shape, and relative position of the first light guide with respect to other elements. In this way, when multiple LED packages are applied to a light-emitting device, the dark bands between adjacent LED packages may be reduced, so that the overall light-emitting effect of the light-emitting device is more uniform. In some embodiments, the light-emitting device may include a surface light source, a backlight source of a display, a dashboard backlight source for a vehicle, etc.

It should be noted that the present disclosure is not limited to the number of LED units 11. In the mentioned embodiments of LED packages, the LED unit 11 may be a single unit, and the LED unit 11 is positioned directly below the bottom portion 13B of the first light guide 13 (not shown in the figure). Taking the LED package of FIG. 2 or 3 as an example, the LED unit 11 may be a single unit, the encapsulant 12 covers the LED unit, and the single LED unit 11 may be arranged directly below the chamfer 13BR or the pointed tip 13BT of the bottom portion 13B of the first light guide 13, and the reflective surface 13R of the first light guide 13 is between the top portion 13T and the bottom portion 13B, and the reflective surface 13R reflects a portion of the light emitted from the single LED unit 11 to the side 12S of the encapsulant 12.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting diode (LED) package, comprising:
a plurality of LED units;
an encapsulant covering the plurality of LED units, wherein the encapsulant has a recessed portion positioned between the plurality of LED units, and the encapsulant has a plurality of side surfaces surrounding the plurality of LED units and the recessed portion; and
a first light guide disposed in the recessed portion of the encapsulant, wherein the first light guide has a top portion and a bottom portion, and an area of the top portion is larger than an area of the bottom portion, wherein the first light guide comprises a plurality of reflective surfaces positioned between the top portion and the bottom portion, and each of the plurality of reflective surfaces corresponds to the plurality of LED units to reflect a portion of light emitted from the plurality of LED units toward the plurality of side surfaces of the encapsulant.

2. The LED package as claimed in claim 1, wherein the encapsulant comprises a light-transmissive portion and a wavelength conversion material dispersed within the light-transmissive portion.

3. The LED package as claimed in claim 1, further comprising a wavelength conversion layer covering outer surfaces of the plurality of LED units.

4. The LED package as claimed in claim 1, wherein an angle between one of the plurality of reflective surfaces and the top portion of the first light guide is between 20 degrees and 70 degrees.

5. The LED package as claimed in claim 1, wherein the first light guide comprises a white resin.

6. The LED package as claimed in claim 1, wherein the top portion of the first light guide has a rough surface.

7. The LED package as claimed in claim 1, wherein the bottom portion of the first light guide has a planar surface, a chamfer, or a pointed tip.

8. The LED package as claimed in claim 1, further comprising a light diffusion layer disposed on a top surface of the encapsulant and surrounding the top portion of the first light guide.

9. The LED package as claimed in claim 1, further comprising a substrate for supporting the plurality of LED units and the encapsulant.

10. The LED package as claimed in claim 9, wherein the top portion of the first light guide has an orthographic projection area on the substrate, and the orthographic projection area occupies 40% to 100% of a total area of the substrate.

11. The LED package as claimed in claim 9, further comprising a second light guide, wherein the second light guide is on the substrate and below the bottom portion of the first light guide.

12. The LED package as claimed in claim 1, wherein one of the plurality of reflective surfaces comprises an inclined surface, a stepped structure, or a curved surface.

13. The LED package as claimed in claim 1, wherein the plurality of LED units are symmetrically disposed around the first light guide with the bottom portion of the first light guide serving as a reference.

14. The LED package as claimed in claim 1, wherein the LED package is substantially shaped as a parallelepiped, the plurality of side surfaces of the encapsulant comprise a first side surface and a second side surface that are parallel to each other, and a third side surface and a fourth side surface that are parallel to each other, and the third side surface and the fourth side surface connect the first side surface and the second side surface respectively.

15. The LED package as claimed in claim 14, wherein the plurality of LED units comprise a first LED unit and a second LED unit that are respectively positioned on opposite sides of the first light guide.

16. The LED package as claimed in claim 15, wherein a long side of the first LED unit and a long side of the second LED unit are parallel to the first side surface and the second side surface of the encapsulant.

17. The LED package as claimed in claim 15, wherein the plurality of LED units further comprise a third LED unit and a fourth LED unit that are respectively positioned on other opposite sides of the first light guide, and the third LED unit and the fourth LED unit are adjacent to the first LED unit and the second LED unit to collectively form a quadrilateral.

18. The LED package as claimed in claim 17, further comprising a substrate wherein the plurality of LED units are disposed on the substrate, wherein in a top view of the LED package, the substrate has a first diagonal, the quadrilateral has a second diagonal, and the first diagonal overlaps the second diagonal.

19. A light-emitting diode (LED) package, comprising:
an LED unit;
an encapsulant covering the LED unit, wherein the encapsulant has a recessed portion, the recessed portion is positioned corresponding to the LED unit, and the encapsulant has a plurality of side surfaces surrounding the LED unit and the recessed portion; and
a first light guide disposed in the recessed portion of the encapsulant, wherein the first light guide has a top portion and a bottom portion, and an area of the top portion is larger than an area of the bottom portion, wherein the first light guide comprises a reflective surface positioned between the top portion and the bottom portion, and the reflective surface reflects a portion of light emitted from the LED unit toward the plurality of side surfaces of the encapsulant.
